(19) United States
(12) Patent Application Publication
(10) Pub. No.: US 2005/0250347 A1
(43) Pub. Date: Nov. 10, 2005

(54) Method and apparatus for maintaining by-product volatility in deposition process

(76) Inventors: Christopher M. Bailey, Horsham (GB); Richard Hogle, Oceanside, CA (US); Simon James Purdon, Mountain View, CA (US); Revati Pradhan-Kasmalkar, San Jose, CA (US); Aaron Daver Sullivan, Sacramento, CA (US); Qing Min Wang, Edison, NJ (US); Ce Ma, Cary, NC (US)

Correspondence Address: THE BOC GROUP, INC., 575 MOUNTAIN AVENUE, MURRAY HILL, NJ, 07974-2064, US

(21) Appl. No.: 11/018,641

(22) Filed: Dec. 21, 2004

Related U.S. Application Data
(60) Provisional application No. 60/533,615, filed on Dec. 31, 2003.

(51) Int. Cl. H01L 21/44

(52) U.S. Cl. 438/785; 118/715

(57) ABSTRACT

A method and apparatus for introducing a fluorine-containing flow stream to a deposition process to maintain process by-product volatility and reduce or eliminate by-product formation and/or interference.

### BACKGROUND OF THE INVENTION

Thin film deposition processes for depositing films of pure and compound materials are known. In recent years, the dominant technique for thin film deposition has been chemical vapor deposition (CVD). A variant of CVD, Atomic Layer Deposition (ALD) has been considered to be an improvement in thin layer deposition in terms of uniformity and conformity, especially for low temperature deposition. ALD was originally termed Atomic Layer Epitaxy, for which a competent reference is Atomic Layer Epitaxy, edited by T. Sunola and M. Simpson (Blackie, Glasgo and London, 1990).

Generally, ALD is process wherein conventional CVD processes are divided into single-monolayer deposition steps, wherein each separate deposition step theoretically goes to saturation at a single molecular or atomic monolayer thickness, and self-terminates. The deposition is the outcome of chemical reactions between reactive molecular precursors and the substrate. In similarity to CVD, elements composing the film are delivered as molecular precursors. The net reaction must deposit the pure desired film and eliminate the “extra” atoms that compose the molecular precursors (ligands).

In the case of CVD, the molecular precursors are fed simultaneously into the CVD reaction chamber. A substrate is kept at a temperature that is optimized to promote chemical reaction between the molecular precursors concurrent with efficient desorption of by-products. Accordingly, the reaction proceeds to deposit the desired thin film.

For ALD applications, the molecular precursors are introduced separately into the ALD reaction chamber. This is done by flowing one precursor (typically a metal to which is bonded to atomic or molecular ligand to make a volatile molecule). The metal precursor reaction is typically followed by inert gas purging to eliminate this precursor from the chamber prior to the introduction of the next precursor.

Thus, in contrast to the CVD process, ALD is performed in a cyclic fashion with sequential alternating pulses of the precursor, reactant and purge gases. Typically, only one monolayer is deposited per operation cycle, with ALD typically conducted at pressures less than 1 Torr.

ALD processes are commonly used in the fabrication and treatment of integrated circuit (IC) devices and other substrates where defined, ultra-thin layers are required. Such ALD processes produce by-products that adhere to and otherwise cause deleterious processing effects in the deposition apparatus components. Such effects include pump seizure, pump failure, impure deposition, impurities adhering to reaction chamber walls, etc. that requires the deposition process to be suspended while the by-products are removed, or the fouled components are replaced. The suspension of the production is timely and thus costly.

Such drawbacks also occur in Chemical Vapor Deposition (CVD) processes. However, such problems often occur with greater frequency during ALD since, in ALD processes, the gases fed into the reaction chamber and the intended reaction is a surface reaction on the substrate being treated (e.g., IC devices). Therefore, in ALD processes, a majority of the supplied gas leaves the reaction chamber “unreacted”, and further mixes with gases from the previous and subsequent reaction steps. As a result, a significant volume of the unreacted gases is available to react outside the reaction chamber in locations such as in the process foreline and the pumps. It is believed that this condition in ALD processes results in higher unwanted non-chamber deposition rates, which leads to pump and foreline “clogging” and resulting in pump failure with respect to both seizure and restart.

Various solutions have been attempted, but are time-consuming, costly, or otherwise impractical for various reasons including space allocation. For example, one current approach being used fits a valve at the exhaust of the reaction chamber. The valve acts to physically switch the flow alternately to one of two forelines and vacuum pumps. The valve operation must be timed to synchronize with the cycle times used to pulse various gases into the reaction chamber. Each pump exhaust must be routed separately to an abatement unit. As a result, this solution is not desirable due to increased processing cost. In addition, this solution is incomplete as portions of the reactant gases may still combine and react before they reach the chamber's exit valve. Other solutions employ a foreline trap, to either trap the process by-product, or selectively trap one or more of the reactant species to avoid cross-reaction. One proposed solution in a CVD process, disclosed in JP 11181421 introduces ClF₃ or F₂ to react with by-products formed during CVD that adhere to pipe surfaces. However, the significant amount of by-product exiting the reaction chamber and the expected proportion of reactivity of the species make this approach unworkable for ALD systems. Rather than introduce separate chemical reactions to break down unwanted deposited by-products, it would be more efficient, less disruptive, less costly and therefore much more desirable to impede by-product accumulation in the first instance.

### SUMMARY OF THE INVENTION

The present invention is directed to a method, system and apparatus for improving the efficiency of a deposition system by decreasing or substantially eliminating the amount of by-products produced during the deposition system by providing an atmosphere to predictably maintain the volatility of produced by-products to prevent unwanted volumes of by-product deposition on the system pump, inner surfaces of the lines and chambers, and on other component surfaces.

Further, the present invention is directed to a method, system and apparatus for improving the efficiency of a deposition system by decreasing or substantially eliminating the amount of by-products produced during the deposition system by providing an atmosphere to predictably re-volatize any deposited by-products that have been deposited on pump and component surfaces.

More specifically, the present invention is directed to a method, system and apparatus for improving the efficiency of a deposition system by decreasing or substantially eliminating the amount of by-products produced during the deposition system by providing a fluorine atmosphere in the deposition process, the atmosphere comprising molecular fluorine (F₂) or fluorine in the radical form (F*), and the fluorine atmosphere introduced to the apparatus in the foreline.

### BRIEF DESCRIPTION OF THE DRAWINGS

The present invention may be better understood, and its numerous objects, features and advantages made apparent to those skilled in the field by referencing the accompanying drawings. For ease of understanding and simplicity, common numbering of elements within the drawings is employed where the element is the same between illustrations.

FIG. 1 is a schematic representation of one embodiment of the present invention wherein fluorine is sourced to the system from NF₃/C₂F₆/SF₆/ClF₃F₂ via a plasma generator.

FIG. 2 is a schematic representation of an embodiment of the present invention wherein fluorine is sourced to the system from a fluorine generator.

FIG. 3 is a schematic representation of an embodiment of the present invention wherein fluorine sourced to the system from an F₂ bottle.

FIG. 4 is a schematic representation of an embodiment of the present invention wherein fluorine is sourced from NF₃/C₂F₆/SF₆/ClF₃/F₂ with no dissociation.

FIG. 5 is a schematic representation of an embodiment of the present invention wherein fluorine sourced from NF₃/C₂F₆/SF₆/ClF₃/F₂ via thermal disassociation.

### DETAILED DESCRIPTION OF THE INVENTION

The present invention now will be described more fully hereinafter with reference to the accompanying drawings, in which preferred embodiments of the invention are shown. This invention may, however, be embodied in many different forms and should not be construed as limited to the embodiments set forth herein; rather, these embodiments are provided so that this disclosure will be thorough and complete, and will fully convey the scope of the invention to those skilled in the art.

The present invention is directed to injecting a gas containing fluorine into a pumping, or pumping and abatement system, in such a way as to keep the process by-product volatile and prevent or substantially eliminate unwanted by-product deposition in the pump and system feed lines, and to re-volatize any deposits that may have formed on the surfaces within the pump and feed lines.

In one embodiment, the present invention is directed to injecting fluorine gas, either in molecular (F₂) or radical (F*) form into the deposition system foreline, preferably at a location in the foreline upstream of the pump. Generally, the volume of gas required is inversely proportional to the reactivity of the gas. Hence, F* would be preferred over elemental fluorine, F₂. However, F* will very quickly recombine to form F₂, although there are design considerations which can affect the rate at which recombination occurs. For the purposes of this invention, the term “fluorine gas” refers to either F₂, or F*, or both unless otherwise indicated.

According to the present invention, there are several viable options for the source of the fluorine gas, where to introduce the gas in the foreline, as well as where to introduce the gas directly into the pump, and how the injection system and pump are arranged with respect to the exhaust gas abatement system. The present invention therefore contemplates all of these options as would be readily understood by one skilled in the gas processing field.

For example, fluorine gas can be supplied to the system delivered from a gas container, cylinder, or “bottle”. However, this is expected only to be acceptable for small-scale investigations to prove the effectiveness of fluorine but for regulatory reasons it is unlikely that the presence of a high pressure fluorine cylinder often will be acceptable.

Further, fluorine gas may be sourced to the apparatuses and systems of the present invention through extraction from a gas stream such as NF₃, C₂F₆, SF₆ or similar using a plasma generator such as the MKS Astron (MKS ASTex Products, Wilmington, Mass.) or similar device to produce fluorine radicals. The fluorine radicals will recombine to F₂ within a fairly short distance. Another method of separating the F₂/F radical from the NF₃/C₂F₆/SF₆ stream would be to use a hollow cathode, as set forth in detail in U.S. Pat. No. 5,951,742, the contents of which are incorporated by reference herein in its entirety.

Still further, the present invention contemplates the use of a fluorine generator, located externally from, or integrated within the system, which electrolyzes aqueous HF into F₂ and H₂. The generator may not require the usually present buffer volume and purification equipment since the present invention may not require highly purified fluorine gas for its intended purpose.

According to the present invention, preferred design considerations for the systems, methods and apparatuses include injecting or introducing the fluorine gas at specific locations in the foreline, preferably near the pumping system. One contemplated location if a booster is incorporated into the foreline is above the booster to better expose the whole of the booster to fluorine. In addition, the fluorine gas stream could be introduced between the booster and the backing pump, which would provide some protection against fluorine backstreaming up the foreline, while giving some fluorine gas exposure to the booster.

Some level of purge directly into the backing pump stages may be necessary to allow F* to reach far enough into the pump to be effective. Additionally, the present invention contemplates abatement of the pump exhaust, which would include fluorine. Indeed, the exhaust is ideally treated upon exit from the chamber exhaust for the intended useful purpose of becoming further fluorine source gas in the present system, or as a fluorine source for a separate operation (i.e., the present method may also become a fluorine production method that may be stored for other use, or recycled to the present processes). The present invention also contemplated the incorporation of various regulating, sensing, and monitoring means for the mitigation of fluorine leaks, and general system compliance and control. Further contemplated considerations and practical advantages of the present systems, methods and apparatuses include: corrosion of materials of construction including static and dynamic seals; stability of process pressure, facilities connections; interlocking of plasma generator of fluorine generator with cleaning gas supply, vacuum pump and abatement; and sharing of fluorine gas source across the quantity of process pumps used on the tool. It is readily understood that should a system have multiple pumps on-line, the fluorine source and support equipment would be shared across all pumps that require fluorine treatment for cleaning.

As previously noted, a majority of the gas supplied to the deposition chamber remains unreacted. The amount of gas introduced to the chamber in generally carefully monitored and controlled, and therefore to provide the desired deposition layer, and it is known how much unreacted gas exits the chamber. It is therefore possible to monitor and control the amount of fluorine gas provided to the foreline in order to optimize the use of the system according to the present invention.

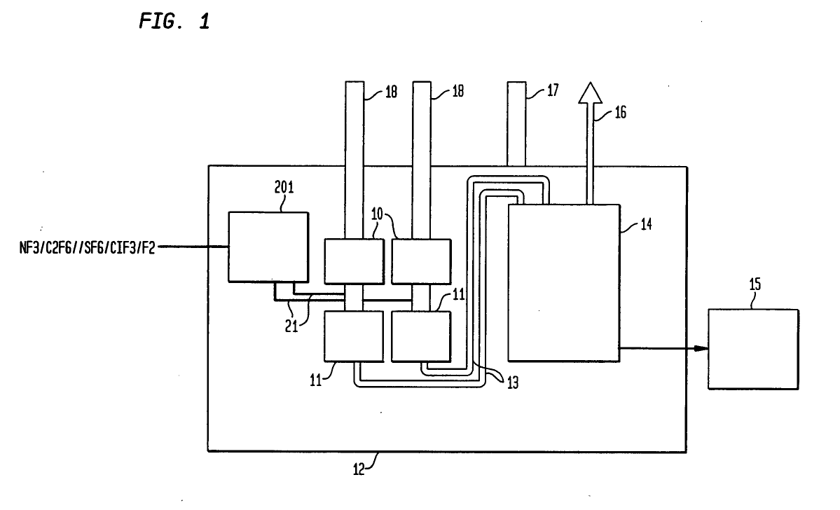

Some embodiments contemplated by the present invention are described below. The most significant differences among the embodiments shown in the FIGS. 1-5 relate to the location of the fluorine gas sourcing and introduction to the system. In each embodiment the vacuum pumping system comprises a backing pump (11) and booster (10) for each foreline (18)—one per wafer reaction or processing chamber on the tool. The pumps exhaust via pipes (13) to an exhaust gas abatement system (14), which is envisaged to be similar in technology and construction to, for example, a thermal oxidizer and wet abatement system. The effluent is piped to the facility exhaust duct (16) while liquid waste is sent to the facility acid waste treatment system (15). The pumps and abatement are housed within an enclosure (12) such as a Zenith style system enclosure, which is extracted to the facility exhaust system via a cabinet extraction system (17). This enclosure is optional for this invention, although it does provide leak detection and containment environments. Similarly the boosters (10) are optionally present.

In each embodiment described herein as well as those shown in FIGS. 1-5, fluorine gas (21) is injected between the booster (10) and the backing pump (11) although it may be equally or more effective to “inject” the fluorine gas into the foreline (18) above the booster, ideally within the enclosure (12). If boosters are not used, the injection point is above the backing pump (11).

In each case the effluent from the pumps needs abatement and the addition of fluorine requires suitable abatement, for example using the thermal oxidizer and wet abatement system (14). It is further understood that the fluorine stream provided according to the present invention can be either a continuous low-level bleed, or a pulsed flow at higher levels, or a combination of both.

The potential arrangements of integrating the pumping systems are shown in the Figures. As shown in FIG. 1, fluorine is sourced from NF₃/C₂F₆/SF₆/ClF₃/F₂ via a plasma generator (201) such as the MKS Astron, a similar generator, or a plasma generator designed specifically and optimized for these applications. The plasma generator (201) preferably is fed via a pipe from a regulated source of NF₃ or SF₆ or C₂F₆ or the like from a container on a back pad. Alternatively, it could be fed from a regulated source from a point of use fluorine generator situated within the fab or on the back pad. Further, hollow cathodes could be used in this application. See, for example, U.S. Pat. No. 5,951,742, incorporated by reference herein.

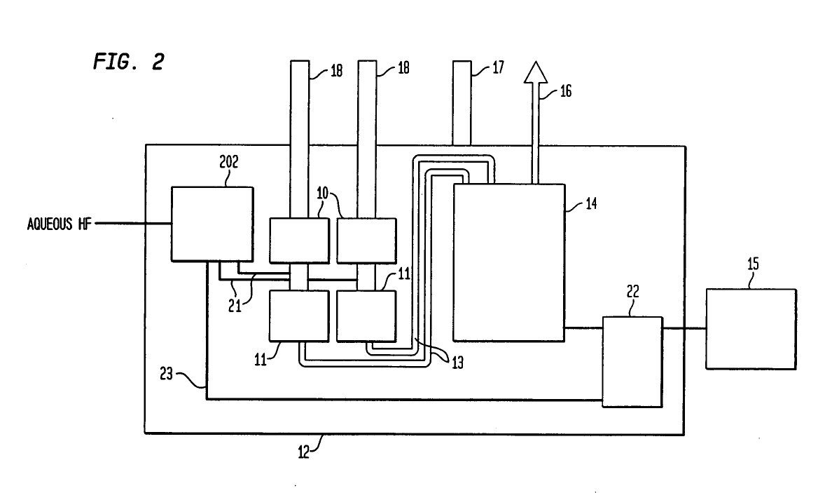

As shown in FIG. 2, fluorine may also be sourced from a fluorine generator (202). This embodiment is in most respects the same as embodiment 1 except that the fluorine source is F₂ electrolytically separated from aqueous HF in the fluorine generator (202). Therefore the output from the fluorine generator (202) is F₂, not F*, as a plasma generator would be required to make F*. Because the liquid output of the gas abatement system contains HF, it is also possible to recover the HF in the waste stream using an HF recovery system (22) and feed back loop (23) to the fluorine generator (202). In this case the pump does not require the purity and flow rate stability that a process chamber does and therefore, some of the components of the typical fluorine generator may be able to be deleted, down rated or shared with other parts of the system. The other elements of this embodiment are the same as those shown in FIG. 1.

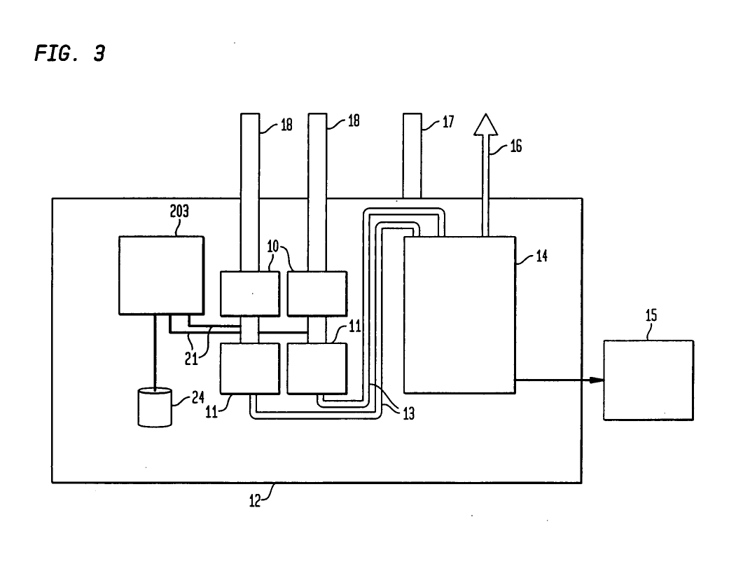

A further embodiment is shown in FIG. 3, wherein fluorine gas may be sourced from an F₂ “bottle” (203), (e.g., 20% F₂ in N₂). In this case, fluorine gas is source from a bottle (203) contained within the system enclosure (12) or located in a separate but nearby gas cabinet. This system utilizes a fluorine control and distribution system (30) as will be readily understood by one skilled in the field of gas manufacture and distribution. The other elements of this embodiment are the same as those shown in FIG. 1.

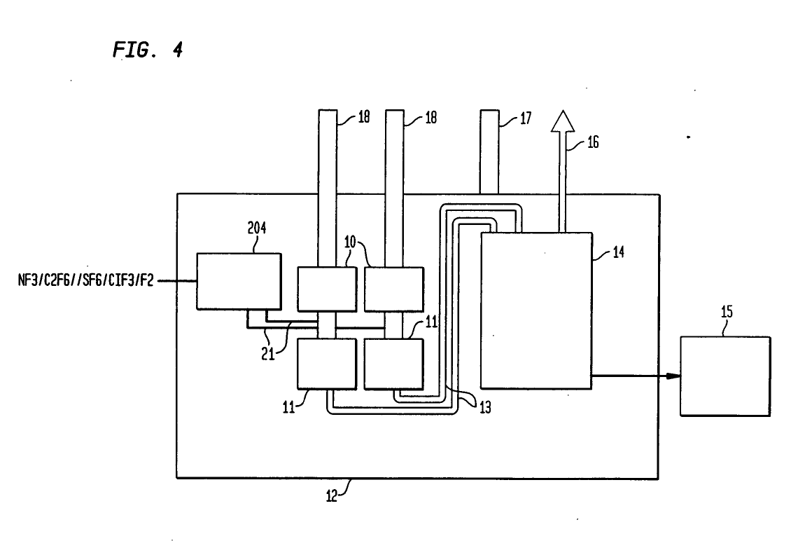

FIG. 4 shows an embodiment where fluorine may be sourced from NF₃/C₂F₆/SF₆/ClF₃F₂ with no dissociation, in which case only a distribution manifold (204) is required, such manifold (204) including the control and monitoring functions. It is also possible that F₂ sourced from an external source could be used in the same manner. The other elements of this embodiment are the same as those shown in FIG. 1.

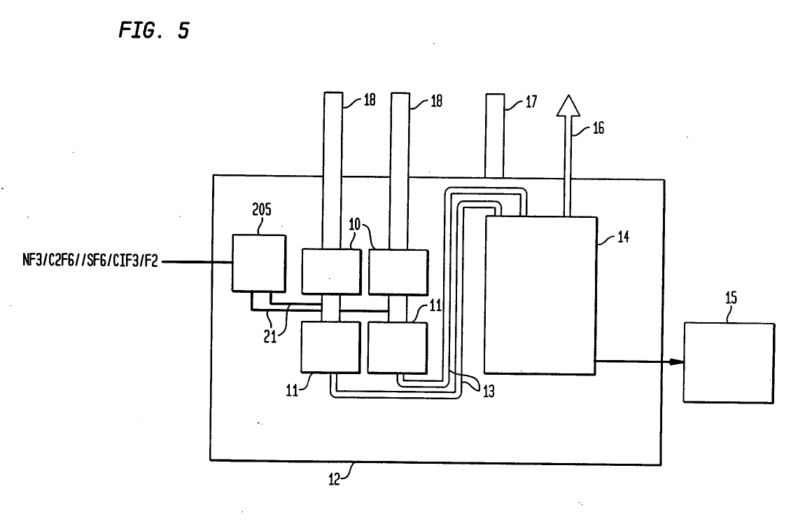

As shown in FIG. 5, fluorine may also be sourced from NF₃/C₂F₆/SF₆/ClF₃/F₂ via thermal disassociation using a thermal cracker (205). The other elements of this embodiment are the same as those shown in FIG. 1.

The methods, systems and apparatuses of the present invention are particularly useful in ALD processes for tungsten deposition as both tungsten nucleation layers and tungsten barrier layers where ammonia-containing species are or are not present. See U.S. Pat. No. 6,635,965, which is incorporated by reference herein in its entirety. When ammonia-containing species are present, the fluorine gas stream will react predictably and in a controlled reaction to produce desired by-products HF and NF₃, which can be isolated downstream and either recycled to the system as further fluorine sources, or delivered to storage facilities for storage or further purification.

### EXAMPLES

Test results confirming the viability of the solutions offered by the present invention were obtained, and are shown in Table 1 below.

TABLE 1

| | F₂ | NF₃ | Ar | Temp | | | | Pressure |
|---|---|---|---|---|---|---|---|---|
| Run # | slm | slm | slm | C. | Plasma | Etch | Time | torr |
| 0 | | 1 | 1 | 30 | yes | fast | min | 2.3 |
| 1 | 0.5 | | 5 | 50 | no | none | 10 | 1.97 |
| 1a | 1 | | 1 | 50 | yes | fast | 6 | 2 |
| 2 | 1 | | 1 | 70 | no | none | 10 | 13 |
| 3 | | 1 | 1 | 70 | no | none | 6 | 22.9 |
| 4 | 0.5 | | 5 | 30 | yes | slow | | 43 |
| 5 | 0.5 | | 5 | 30 | yes | slow | | 3.7 |
| 6 | 0.5 | | 2 | 30 | yes | slow | | 3.3 |
| 7 | 1.5 | | 1.5 | 30 | yes | slow | | 30 |
| 7a | 1.77 | | 1.7 | 30 | yes | fast | | 5.6 |

Many modifications and other embodiments of the invention will come to mind to one skilled in the art to which this invention pertains having the benefit of the teachings presented in the foregoing descriptions and the associated drawings. Therefore, it is to be understood that the invention is not to be limited to the specific embodiments disclosed and that modifications and other embodiments are intended to be included within the scope of the appended claims. Although specific terms are employed herein, they are used in a generic and descriptive sense only and not for purposes of limitation.

1. A method for depositing thin films onto a substrate comprising the steps of:
providing a deposition apparatus comprising a reaction chamber, said chamber having an inlet, and an exhaust in communication with a foreline, said foreline in communication with a pump;
providing a substrate to said chamber;
introducing a component to be deposited onto said substrate to said chamber;
depositing said component onto said substrate; and
introducing a fluorine-containing component to said foreline.

2. The method of claim 1, wherein said fluorine-containing component is selected from the group consisting of fluorine and fluorine radicals.

3. The method of claim 1, wherein said fluorine-containing component is provided from a fluorine source apparatus selected from the group consisting of a fluorine container, a fluorine generator, and a fluorine plasma generator.

4. The method of claim 1, wherein said fluorine-containing component is generated from a fluorine precursor selected from the group consisting of F₂, NF₃, C₂F₆, SF₆, and ClF₃.

5. The method of claim 1, wherein said fluorine-containing component is introduced to the pump.

6. The method of claim 1, wherein said fluorine-containing component is introduced to said foreline between said pump and a booster.

7. The method of claim 1, wherein said fluorine-containing component is introduced to said foreline upstream of said pump.

8. The method of claim 1, wherein said substrate is an integrated circuit.

9. The method of claim 1, wherein said substrate is a wafer.

10. The method of claim 1, wherein said component comprises a material selected from the group consisting of rhenium-containing, molybdenum-containing, titanium-containing and tungsten-containing compounds.

11. The method of claim 1, wherein said component comprises an ammonia-containing compound.

12. The method of claim 1, further comprising the steps of:
providing said component in a first stream flow at a predetermined amount such that a portion of said first stream remains unreacted and exits said chamber from said exhaust;
contacting said unreacted portion of said first stream with said fluorine-containing component in said foreline; and
creating a by-product from a reaction of said first stream and said fluorine-containing component.

13. The method of claim 12, wherein said by-product is purified.

14. The method of claim 12, wherein said by-product is HF or NF₃.

15. The method of claim 12, wherein said by-product is recycled for use in the deposition process.

16. The method of claim 12, wherein said by-product is stored.

17. The method of claim 1, wherein said deposition method is selected from the group consisting of chemical vapor deposition and atomic level deposition.

18. An apparatus for depositing thin films onto a substrate comprising:
a reaction chamber, said chamber having an inlet, and an exhaust in communication with a foreline, said foreline in communication with a pump;
a first stream source in communication with said inlet to provide a first stream to said chamber;
a second stream source in communication with said foreline to provide a second stream to said foreline, said second stream comprising a fluorine-containing compound; and
means for regulating said first stream and said second stream such that said second stream is provided to said foreline in an amount sufficient to react with an amount of said first stream.

19. The apparatus of claim 18, wherein said fluorine-containing component is selected from the group consisting of fluorine and fluorine radicals.

20. The apparatus of claim 18, wherein said second stream source is selected from the group consisting of a fluorine container, a fluorine generator, and a fluorine plasma generator.

21. The apparatus of claim 18, wherein said fluorine-containing compound is generated from a fluorine precursor selected from the group consisting of F₂, NF₃, C₂F₆, SF₆, and ClF₃.

22. The apparatus of claim 18, wherein said second stream is introduced to said pump.

23. The apparatus of claim 18, further comprising a booster in communication with the foreline upstream of said pump, and wherein said second stream is introduced to said foreline between said pump and said booster.

24. The apparatus of claim 18, wherein said second stream is introduced to said foreline upstream of the pump.

25. The apparatus of claim 18, wherein said first stream comprises a material selected from the group consisting of rhenium-containing, molybdenum-containing, titanium-containing and tungsten-containing compounds.

26. The apparatus of claim 18, wherein said first stream comprises an ammonia-containing compound.

27. The apparatus of claim 18, wherein said apparatus is selected from the group consisting of chemical vapor deposition apparatus and atomic level deposition apparatus.

28. The apparatus of claim 18, wherein said first stream and said second stream react to form a by-product.

29. The apparatus of claim 28, wherein said by-product is purified.

30. The apparatus of claim 28, wherein said by-product is HF or NF₃.

31. The apparatus of claim 28, further comprising a recycle loop for directing said by-product to said foreline.

32. The apparatus of claim 28, further comprising a storage chamber for said by-product.
